(19) United States
(12) Patent Application Publication
(10) Pub. No.: US 2013/0319516 A1
(43) Pub. Date: Dec. 5, 2013

(54) METHOD FOR MANUFACTURING FRONT ELECTRODE OF SOLAR CELL AND SOLAR CELL DEVICE MANUFACTURED BY SAME

(71) Applicants: Jung-Wu Chien, Hsin-chu County (TW); Chuan-Chi Chen, Taipei City (TW)

(72) Inventors: Jung-Wu Chien, Hsin-chu County (TW); Chuan-Chi Chen, Taipei City (TW)

(73) Assignee: Inventec Solar Energy Corporation, Taoyuan County (TW)

(21) Appl. No.: 13/633,175

(22) Filed: Oct. 2, 2012

(30) Foreign Application Priority Data
Jun. 4, 2012 (TW) 101212101

(51) Int. Cl. H01L 31/0224; H01L 31/18

(52) U.S. Cl. 136/256; 438/72; 257/E31.124

(57) ABSTRACT

A method for manufacturing a front electrode of a solar cell and a solar cell device manufactured by the same method are provided. The method includes steps of providing a substrate; performing a first screen printing process to form at least one first electrode over the substrate; and performing a second screen printing process to form at least one row of a second electrode structure over the substrate. The first electrode is formed with a strip body and a plurality of salients connected to the strip body. The second electrode structure has a plurality of sections of finger electrodes, wherein first ends of the finger electrodes directly contact with first surfaces of the salients of the first electrode, respectively, without extending to the strip body.

### FIELD OF THE INVENTION

The present invention relates to a solar cell device and a manufacturing method thereof, and more particularly to a method for manufacturing a front electrode of a solar cell and a solar cell device manufactured by using the method.

### BACKGROUND OF THE INVENTION

In a conventional process for manufacturing solar cells, a screen printing technology is used for producing front metal contact electrodes. Generally, the screen printing process may simultaneously form contact electrodes with different width in a single printing procedure. Alternatively, it may be performed with twice printing to individually form contact electrodes with different width.

By the screen printing process performed with a single screen, a plurality of fine finger electrodes 120a and wider busbar electrodes 130a can be simultaneously printed onto the substrate 110, as shown in FIG. 1A. In view of improvement of an aperture ratio of the contact electrode layer of the solar cell and reduction of resistance of the contact electrode, it is preferred to have a fine and thick finger electrode. However, the manufacturing process performed with a single screen is unable to produce adaptive structures depending on differences in properties, such as material or thickness of electrodes, between the finger electrode 120a and the busbar electrode 130a. In addition, in the contact electrodes manufactured by this method, a breach might be made at the linking part between the finger electrode and the busbar electrode.

The screen printing process performed with twice printing includes printing the finger electrodes 120b onto the substrate 110 first, and then printing the busbar electrode 130b onto the substrate 110 with the finger electrodes 120b, as shown in FIG. 1B. FIG. 1C is a schematic cross-sectional view of a solar cell device having contact electrodes, which is taken along a-a′ line of FIG. 1B. In the manufacturing process performed with twice printing, the finger electrodes 120b and the busbar electrodes 130b are printed in sequence onto the substrate 110, so the busbar electrodes 130b are formed on a rugged surface, as shown in FIG. 1C, where the finger electrodes 120b with a certain thickness have been formed. This rugged surface would cause uneven coating of a flux onto the depressions and deteriorate the quality of wires welded onto the busbar electrodes 130b. Thus the reliability of the solar cell is adversely affected.

In view of the aforementioned reasons, there is a need to modify the structure of contact electrodes of a solar cell and contemplate a new manufacturing method to reduce cost and improve reliability of a solar cell device.

### SUMMARY OF THE INVENTION

The present invention provides a method for manufacturing a front electrode of a solar cell and a solar cell device manufactured by using the method, so as to improve a reliability of the device.

In order to achieve the aforementioned advantages or other merits, a method for manufacturing a front electrode of a solar cell is provided in an embodiment of the present invention. The method includes providing a substrate first; performing a first screen printing process to form at least one first electrode over the substrate; and performing a second screen printing process to form at least one row of a second electrode structure over the substrate. The first electrode is formed with a strip body and a plurality of salients connected to the strip body. The second electrode structure includes a plurality of sections of finger electrodes, wherein first ends of the finger electrodes directly contact with first surfaces of the salients of the first electrode, respectively, without extending to the strip body.

In an embodiment of the present invention, the first surfaces of the salient are top surfaces opposite to the substrate.

In an embodiment of the present invention, the first surfaces of the salients are bottom surfaces facing the substrate.

In an embodiment of the present invention, in the aforementioned first screen printing process, a plurality of the first electrodes are formed, each serving as a busbar electrode formed with the salients on opposite sides of the strip body or an edge electrode formed with the salients on a single side of the strip body.

In an embodiment of the present invention, the aforementioned second ends of the finger electrodes are in direct contact with the salients of another one of the first electrodes without extending to the strip body of the another first electrode, wherein the first electrode in contact with the first ends of the finger electrodes and the another first electrode in contact with the second ends of the finger electrodes are both busbar electrodes, or one busbar electrode and one edge electrode.

In an embodiment of the present invention, the aforementioned strip body of the first electrode is substantially perpendicular to each of the finger electrodes.

In an embodiment of the present invention, the finger electrodes have a thickness greater than that of the first electrode.

In an embodiment of the present invention, in the aforementioned second screen printing process, a patterned metal screen different from that used in the first screen printing is used to form the second electrode structure.

In an embodiment of the present invention, the first screen printing process and the second screen printing process are performed on the aforementioned substrate formed with a solar cell structure.

In an embodiment of the present invention, the first screen printing process and the second screen printing process are performed on the aforementioned substrate formed with a solar cell substrate and an anti-reflective layer on the solar cell structure.

The present invention further provides a solar cell device manufactured by using the aforementioned method for manufacturing a front electrode of the solar cell. The solar cell device includes a substrate, at least one first electrode and at least one row of second electrode structure. The first electrode and the second electrode structure are all disposed over the substrate. The first electrode is formed with a strip body and a plurality of salients connected to the strip body. The second electrode structure has a plurality of sections of finger electrodes, wherein first ends of the finger electrodes directly contact with first surface of the salients of the first electrode, respectively, without extending to the strip body.

In summary, according to the present invention, a twice screen printing process is adopted to result in a modified configuration of front electrode. The resulting structure has the busbar electrodes overlapped with the corresponding finger electrodes only in salients. Since the structure of the strip bodies of the busbar electrodes are not affected by the formation of the finger electrodes, the top surface of the strip bodies as a hole can be flattened and reliability of the device can be enhanced. In this manner, poor welds resulting from the uneven surface of the busbar electrodes can be avoided. In addition, the manufacturing condition for the busbar electrodes/edge electrodes and the finger electrodes can be individually and adaptively adjusted. Also for this reason, manufacturing costs can be reduced with improved conductivity of the finger electrodes.

For making the above and other purposes, features and benefits become more readily apparent to those ordinarily skilled in the art, the preferred embodiments and the detailed descriptions with accompanying drawings will be put forward in the following descriptions.

### BRIEF DESCRIPTION OF THE DRAWINGS

The present invention will become more readily apparent to those ordinarily skilled in the art after reviewing the following detailed description and accompanying drawings, in which:

FIG. 1A is a schematic diagram of a conventional solar cell device having front metal contact electrodes produced by using a single screen printing process;

FIG. 1B is a schematic diagram of a conventional solar cell device having front metal contact electrodes produced by using a twice screen printing process;

FIG. 1C is a schematic cross-sectional view of a solar cell device having contact electrodes, which is taken along a-a′ line of FIG. 1B;

FIGS. 2A-2C are schemes illustrating a process for manufacturing front electrodes of a solar cell in accordance with an embodiment of the present invention;

FIG. 2D is a schematic cross-sectional view of a solar cell device having contact electrodes, which is taken along b-b′ line of FIG. 2C;

FIG. 2E is a schematic cross-sectional view of a solar cell device with contact electrodes, which is taken along c-c′ line of FIG. 2C;

FIG. 3A is a schematic diagram illustrating a structure of a solar cell device with contact electrodes produced by using a manufacturing method in accordance with another embodiment of the present invention;

FIG. 3B is a schematic cross-sectional view of a solar cell device with contact electrodes, which is taken along d-d′ line of FIG. 3A; and

FIG. 3C is a schematic cross-sectional view of a solar cell device with contact electrodes, which is taken along e-e′ line of FIG. 3A.

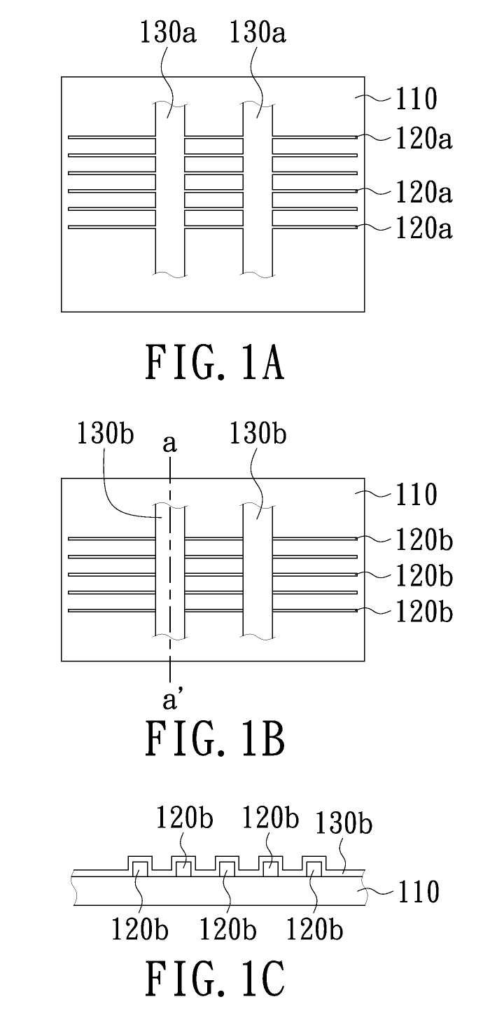

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

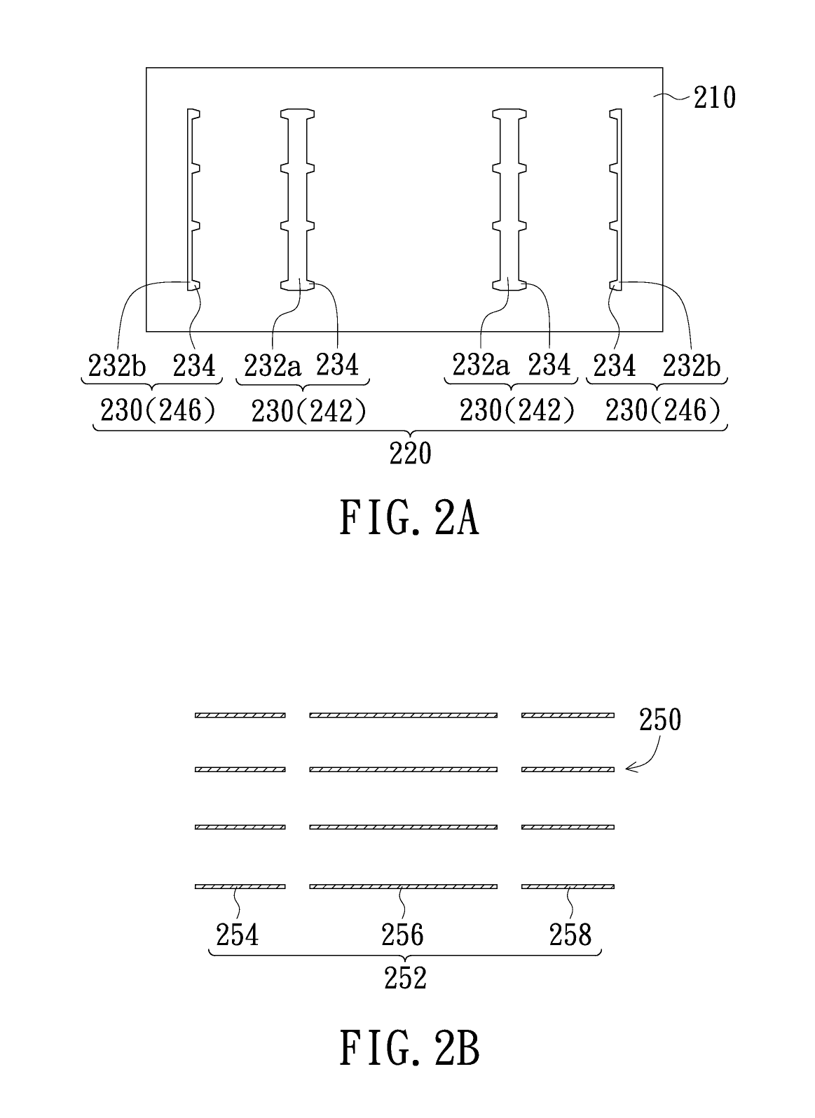

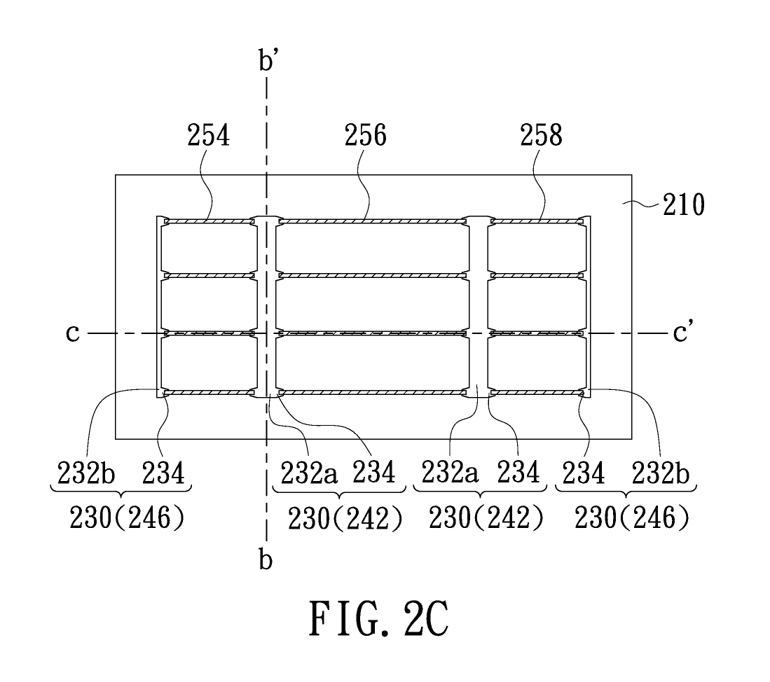

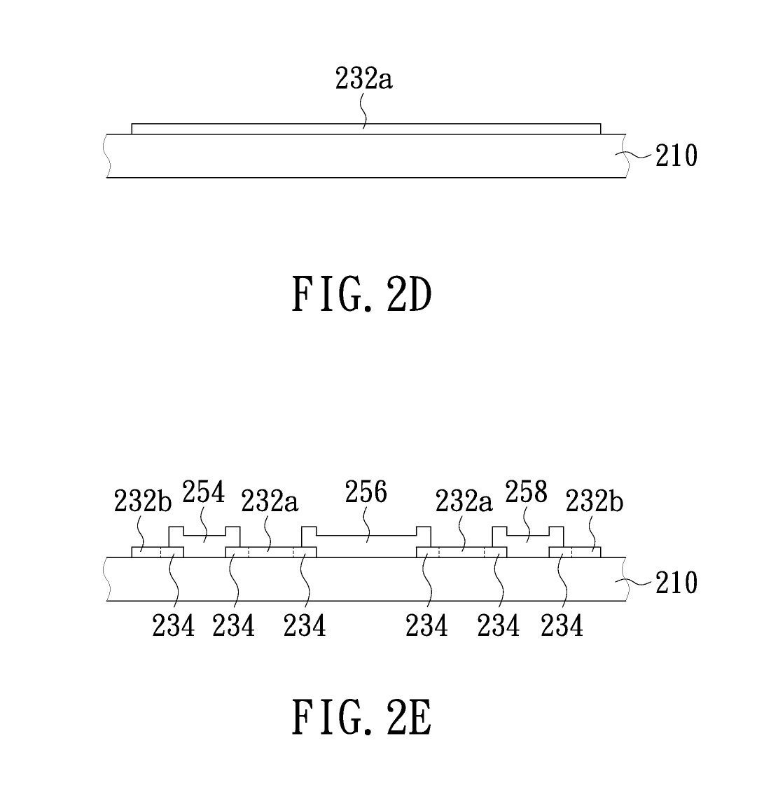

FIGS. 2A-2C are schemes illustrating a process for manufacturing front electrodes of a solar cell in accordance with an embodiment of the present invention. Please refer to FIG. 2A. A substrate 210 is provided. Then a first screen printing process is performed to form a first patterned electrode 220 on the substrate 210. The substrate 210, for example, may be a semiconductor substrate or a glass substrate, on which a solar cell structure and an anti-reflective layer have been formed. In an embodiment, the anti-reflective layer is disposed over the solar cell structure (not shown in figures), and the first patterned electrode 220 is, for example, disposed over the anti-reflective layer.

The first patterned electrode 220 includes at least one first electrode 230, wherein each first electrode 230 is formed with a strip body 232a (or 232b) and a plurality of salients 234 located at and protruding from at least one side of the strip body 232a, 232b. In FIG. 2A, the first patterned electrode 220 having a plurality of the first electrode 230 is illustrated as an example, but the number of the first electrode 230 used in the present invention is not to be limited to that shown in the figure.

In this embodiment, the first electrode 230 may serve as a busbar electrode 242 or an edge electrode 246. In FIG. 2A, two busbar electrodes 242 and two edge electrodes 246 are illustrated while the number of the first electrodes 230 is not to be limited to that shown in the figure. Each of the busbar electrodes 242 is provided with the salients 234 at both sides. On the other hand, each of the edge electrodes 246 is provided with the salients 234 only at the side facing to the neighboring busbar electrode 242. As shown in FIG. 2A, the edge electrodes 246 are disposed near edges of the substrate 210 while the busbar electrodes 242 are disposed inside the substrate 210 from the edge electrodes 246. The strip bodies 232a and 232b of the busbar electrodes 242 and the edge electrodes 246 are parallel to one another. Generally, a width of the strip body 232a of the busbar electrode 242 is greater than that of the strip body 232b of the edge electrode 246. A projected shape of each of the salients 234 can be, for example, but not limited to, a circle, a triangle, a trapezoid, a square or another polygon.

Please refer to FIG. 2B and FIG. 2C. After completing the first screen printing process, a second screen printing process is performed to form a second patterned electrode 250 (as shown in FIG. 2B) onto the substrate 210. The resulting substrate 210 is shown in FIG. 2C.

The second patterned electrode 250 includes at least one row of second electrode structure 252. Each second electrode structure is formed of a plurality of sections of finger electrodes. The number of the finger electrodes in each row of second electrode structure 252 varies with the number of the first electrodes 230 as shown in FIG. 2A. For exemplification purpose only, in the embodiment as illustrated in FIG. 2B, each of the second electrode structures 252 includes three sections of finger electrodes 254, 256, 258 as four first electrodes 230 are shown in FIG. 2A. Both ends of each of the finger electrodes 254, 256, 258 are directly stacked onto top surfaces of the salients 234 without extending to the strip bodies 232a, 232b of the neighboring first electrodes 230, as shown in FIG. 2C. Furthermore, each of the finger electrodes 254, 256, 258 is perpendicular to the strip bodies 232a, 232b of the neighboring first electrodes 230. A width of any of the salients 234 is preferably equal to or greater than that of the finger electrode 254, 256, 258 stacked thereon in order to prevent from any problem resulting from misalignment of the finger electrode 254, 256, 258 from the corresponding salient 234. Besides, an outstanding length of any of the salients 234 is less than a length of the finger electrode 254, 256, 258 stacked thereon, and a film thickness of any of the finger electrode 254, 256, 258 is greater than that of the associated first electrodes 230.

More particularly, in the embodiment shown in FIG. 2C, one end of each of the finger electrodes 254, 256, 258 is directly stacked on a top surface of one corresponding salient 234 while the other end is directly stacked on the top surface of another corresponding salient unit 234. On the other hand, both ends of each of the finger electrodes 254, 256, 258 are exempting from extending to the neighboring strip bodies 232a and/or 232b. The film thickness of each of the finger electrodes 254, 256, 258 is greater than that of any of the busbar electrodes 242 and edge electrodes 246, and the width of the strip body 232a of each of the busbar electrodes 242 is greater than that of any of the finger electrodes 254, 256, 258.

FIG. 2D is a schematic cross-sectional view of a solar cell device with contact electrodes, which is taken along b-b′ line of FIG. 2C. FIG. 2E is a schematic cross-sectional view of a solar cell device with contact electrodes, which is taken along c-c′ line of FIG. 2C. The busbar electrodes 242 produced according to the manufacturing method of the present invention are substantially at the same horizontal level, and basically have a flat surface as a whole. FIG. 2E schematically illustrates the configuration of the finger electrodes 254, 256, 258 stacked on the salients 234 of the busbar electrodes 242, and shows the relative positions of the finger electrodes 254, 256, 258 and the busbar electrodes 242.

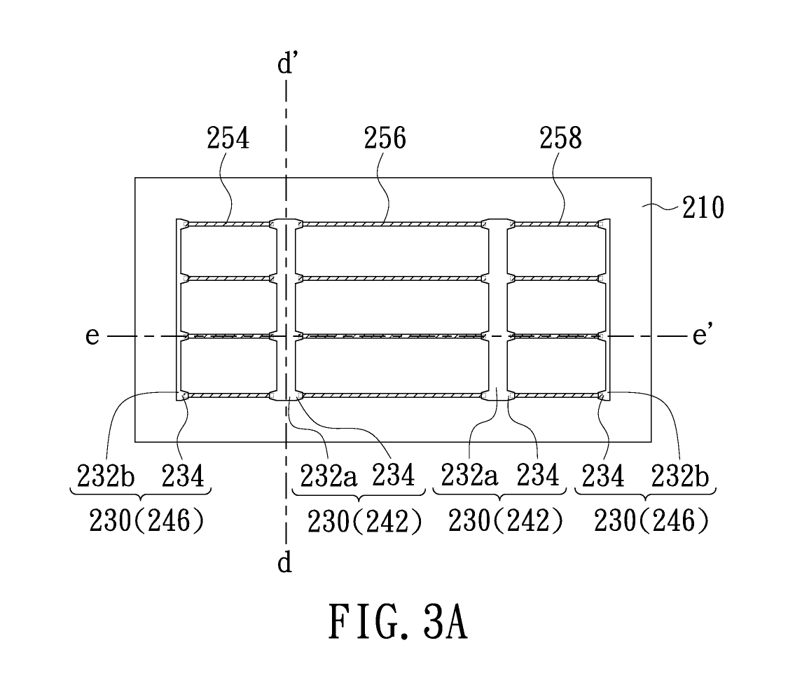

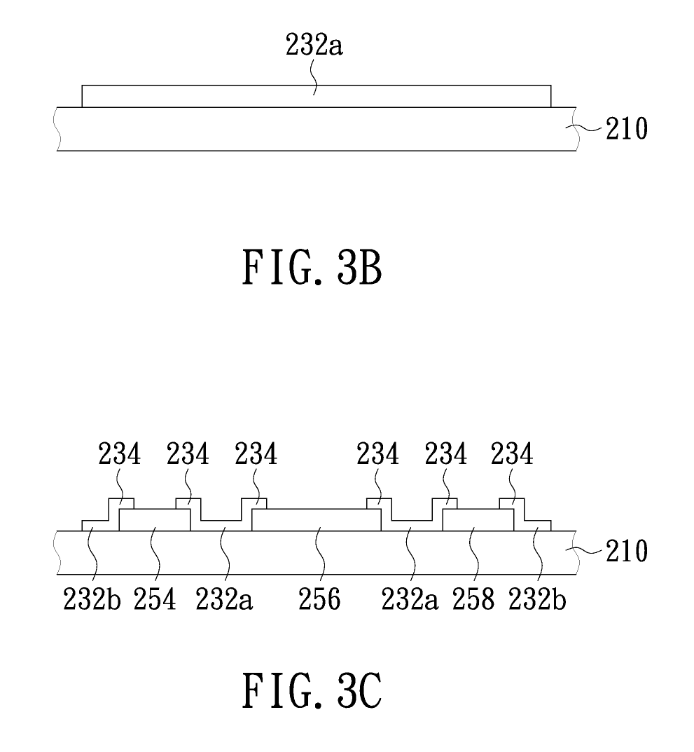

FIG. 3A is a schematic diagram illustrating a structure of a solar cell device having contact electrodes produced by using a manufacturing method in accordance with another embodiment of the present invention. FIG. 3B is a schematic cross-sectional view of a solar cell device with contact electrodes, which is taken along d-d′ line of FIG. 3A. FIG. 3C is a schematic cross-sectional view of a solar cell device with contact electrodes, which is taken along e-e′ line of FIG. 3A

Another embodiment of a manufacturing method of front electrodes of a solar cell according to the present invention will be described hereinafter with reference to FIG. 2A, FIG. 2B and FIG. 3A. In this manufacturing method, the second screen printing process is performed first to form the second patterned electrode 250 including at least one row of the second electrode structure 252 onto the substrate 210 (as shown in FIG. 2B), wherein the second electrode structure 252 is formed with a plurality of sections of the finger electrodes 254, 256, 258. Afterwards, the first screen printing process is performed to form the first patterned electrode 220 including at least one the first electrode 230 (shown in FIG. 2A) onto the substrate 210 with the second patterned electrode 250, wherein the first electrode 230 is formed with the strip body 232a, 232b and a plurality of the salients 234, and the first electrode 230 may serve as the busbar electrode 242 or the edge electrode 246.

The structure of the resulting solar cell device is shown in FIG. 3A. As shown, each of the salients 234 is directly stacked onto the top surface of the finger electrode 254, 256, 258, while the strip body 232a, 232b of each of the first electrodes 230 is staggered from any of the finger electrodes 254, 256, 258. It can be seen from FIG. 3B that the strip bodies 232a of the busbar electrodes 242 are formed substantially at the same horizontal level and have a flat top surface as a whole. FIG. 3C further shows the configuration as a cross-sectional view. That is, the salients 234, other than the strip bodies 232a, of the busbar electrodes 242 are stacked on the top surfaces of the corresponding finger electrodes 254, 256, 258.

In a solar cell device, a finger electrode is usually produced to have a finer and thicker film than that of a busbar electrode or an edge electrode. An aperture ratio of the solar cell device can be enhanced with reduction of the width of the finger electrodes. On the other hand, impedance of the finger electrode can be reduced with the thickened film. In general, the requirement on the material of a finger electrode is higher than that of a busbar electrode or an edge electrode. In accordance with the present invention, the finger electrodes and the the busbar electrodes/edge electrodes, are produced by separate processes so as to optimize the manufacturing conditions.

In an embodiment, the first screen printing process for producing the busbar electrode 242 and the edge electrode 246 may be performed by way of a conventional screen (such as a stencil with mesh). The second screen printing process for producing the finger electrodes 254, 256, 258 may be performed by way of a patterned metal screen (not shown in figures). A pattern of the metal screen may be formed by laser cutting so that the metal screen may substantially have a 100% ink transit rate for producing the fine and thick finger electrode 254, 256, 258 in a single screen printing process. Furthermore, in view of reduction in cost, different ink materials may used for producing the finger electrodes 254, 256, 258 and the busbar electrode 242/edge electrode 246 in the first and the second screen printing process, respectively.

In summary, according to the present invention, a twice screen printing process is adopted to result in a modified configuration of front electrode. The resulting structure has the busbar electrodes overlapped with the corresponding finger electrodes only in salients. Since the structure of the strip bodies of the busbar electrodes are not affected by the formation of the finger electrodes, the top surface of the strip bodies as a hole can be flattened and reliability of the device can be enhanced. In this manner, poor welds resulting from the uneven surface of the busbar electrodes can be avoided. In addition, the manufacturing conditions for the busbar electrodes/edge electrodes and the finger electrodes can be individually and adaptively adjusted. Also for this reason, manufacturing costs can be reduced with improved conductivity of the finger electrodes.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method for manufacturing a front electrode of a solar cell, comprising:
providing a substrate;
performing a first screen printing process to form at least one first electrode over the substrate, wherein the first electrode is formed with a strip body and a plurality of salients connected to the strip body; and
performing a second screen printing process to form at least one row of a second electrode structure over the substrate, wherein the second electrode structure includes a plurality of sections of finger electrodes, and first ends of the finger electrodes directly contact with first surfaces of the salients of the first electrode, respectively, without extending to the strip body.

2. The method according to claim 1, wherein the first surfaces of the salients are top surfaces opposite to the substrate.

3. The method according to claim 1, wherein the first surfaces of the salients are bottom surfaces facing the substrate.

4. The method according to claim 1, wherein in the first screen printing process, a plurality of the first electrodes are formed, each serving as a busbar electrode formed with the salients on opposite sides of the strip body or an edge electrode formed with the salients on a single side of the strip body.

5. The method according to claim 4, wherein second ends of the finger electrodes are in direct contact with the salients of another one of the first electrodes without extending to the strip body of the another first electrode, wherein the first electrode in contact with the first ends of the finger electrodes and the another first electrode in contact with the second ends of the finger electrodes are both busbar electrodes, or one busbar electrode and one edge electrode.

6. The method according to claim 1, wherein the strip body of the first electrode is substantially perpendicular to each of the finger electrodes.

7. The method according to claim 1, wherein the finger electrodes have a thickness greater than that of the first electrode.

8. The method according to claim 1, wherein in the second screen printing process, a patterned metal screen different from that used in the first screen printing is used to form the second electrode structure.

9. The method according to claim 1, wherein the first screen printing process and the second screen printing process are performed on the substrate formed with a solar cell structure.

10. The method according to claim 1, wherein the first screen printing process and the second screen printing process are performed on the substrate formed with a solar cell structure and an anti-reflective layer on the solar cell structure.

11. A solar cell device, comprising:
a substrate;
at least one first electrode, disposed over the substrate and formed with a strip body and a plurality of salients connected to the strip body; and
at least one row of a second electrode structure, disposed over the substrate and including a plurality of sections of finger electrodes, wherein first ends of the finger electrodes directly contact with first surfaces of the salients of the first electrode, respectively, without extending to the strip body.

12. The solar cell device according to claim 11, wherein the first surfaces of the salients are top surfaces opposite to the substrate.

13. The solar cell device according to claim 11, wherein the first surfaces of the salients are bottom surfaces facing the substrate.

14. The solar cell device according to claim 11, a plurality of the first electrodes is further comprised, each serving as a busbar electrode formed with the salients on opposite sides of the strip body or an edge electrode formed with the salients on a single side of the strip body.

15. The solar cell device according to claim 14, wherein the strip body of the busbar electrodes have a width greater than that of the finger electrodes.

16. The solar cell device according to claim 14, wherein second ends of the finger electrodes are in direct contact with the salients of another one of the first electrode without extending to the strip body of the another first electrode, wherein the first electrode in contact with the first ends of the finger electrodes and the another first electrode in contact with the second ends of the finger electrodes are both busbar electrodes, or one busbar electrode and one edge electrode.

17. The solar cell device according to claim 11, wherein the strip body of the first electrode is substantially perpendicular to each of the finger electrodes.

18. The solar cell device according to claim 11, wherein the finger electrodes have a thickness greater than that of the first electrode.

19. The solar cell device according to claim 11, further comprises a solar cell structure disposed over the substrate, wherein the first electrode and the second electrode structure are disposed over the solar cell structure.

20. The solar cell device according to claim 19, further comprises a anti-reflective layer disposed over the solar cell structure, wherein the first electrode and the second electrode structure are disposed over the anti-reflective layer.
